(19) United States
(12) Patent Application Publication
(10) Pub. No.: US 2002/0151170 A1
(43) Pub. Date: Oct. 17, 2002

(54) Method of forming polycrystalline CoSi2 salicide and products obtained thereof

(76) Inventors: Karen Maex, Herent (BE); Christophe Detavernier, Brugge (BE); Roland Vanmeirhaeghe, Pinte (BE); Muriel de Potter de ten Broeck, Leuven (BE); Anne Lauwers, Aartselaar (BE)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/552,980

(22) Filed: Apr. 21, 2000

Related U.S. Application Data
(63) Continuation-in-part of application No. 09/309,455, filed on Jun. 26, 1998.
(63) Continuation of application No. 09/055,645, filed on Apr. 6, 1998, now abandoned.
(63) Continuation-in-part of application No. 08/658,182, filed on Jun. 4, 1996, now Pat. No. 5,780,362.
(60) Provisional application No. 60/161,386, filed on Oct. 26, 1999.

(51) Int. Cl. H01L 21/4763

(52) U.S. Cl. 438/638; 438/683

(57) ABSTRACT

The present invention is related to a method of forming a polycrystalline cobalt disilicide or another near noble metal silicide on a silicon substrate. The method comprises the steps of depositing a layer or layers comprising a cobalt-alloy (Ni, Pd, Pt) and a refractory metal on at least a part of said substrate, said part comprising at least a first and a second part, said second part being covered; thereafter heating said silicon substrate in a first heating step and a second heating step and therebetween treating said substrate with at least one chemical solution, said chemical solution selectively etching non-silicidecobalt (or Ni, Pd, Pt) and said refractory metal and cobalt-refractory (or Ni, Pd, Pt-refractory) metal alloys from said substrate except from said first part.

### RELATED APPLICATIONS

The present application claims the priority of U.S. provisional patent application Ser. No. 60/161,386 filed Oct. 26, 1999. The present application is also a continuation-in-part of U.S. patent application Ser. No. 09/309,455, which is a continuation-in-part in-part of U.S. patent application Ser. Nos. 09/055,645 and 08/658,182 (now U.S. Pat. No. 5,780,362). The disclosures of all of these previous applications are hereby incorporated in their entirety by reference.

### FIELD OF THE INVENTION

The present invention is related to the field of semiconductor device processing. More particularly, the present invention relates to a method for the fabrication of CoSi₂ salicides from Ni—Co—Ti alloys and for the fabrication of other near noble metal silicides such as NiSi, PtSi, and Pd₂Si.

### BACKGROUND OF THE INVENTION

Silicides are known in the art. Metal silicide thin films are commonly used in microelectronic circuits for a variety of applications such as interconnects, contacts, and for the formation of transistor gates. Cobalt disilicide (CoSi₂) and mainly titanium disilicide (TiS₂) are preferentially used in Ultra or Large Scale Integrated Semiconductor devices with submicron design rules. CoSi₂ and TiSi₂ silicide phases are formed through the reaction of cobalt and titanium with silicon to form cobalt disilicide (CoSi₂) and titanium disilicide (TiSi₂), respectively. The silicide layer has a lower sheet resistance than the sheet resistance of silicon.

It is well known in the state of the art, as described in U.S. Pat. No. 5,047,367 (incorporated herein by reference in its entirety), to form CoSi₂ and TiSi₂ salicides (self-aligned silicides) on silicon for the purpose of manufacturing semiconductor devices. An illustrative example of such salicide technology can be described as follows. To make contact to device regions underlying a dielectric on the surface of the silicon substrate, first an opening or via (contact via) in the dielectric over the region to be contacted is made, and next the contact via is filled with a conductive material. In smaller geometry devices, those of one micron or less, the contact to doped silicon is inadequate due to poor contact resistance integrity. For these devices, silicides of refractory or near-noble metals, such as titanium or cobalt, are used to shunt the resistance of the highly doped silicon. The metal is first deposited followed by a heating step to form the silicide on the substrate in the regions exposed by source, drain, and gate areas. The non-silicided metal remaining on the dielectric surface and also on the formed silicide is then selectively etched. Because the silicide is formed only on those regions where there is silicon exposed, that is, the active device regions and the gate region, and because the remaining metal can be selectively etched without a masking step, the structure formed by this process is self aligned. This process is an example of self aligned silicide technology (Salicide Technology).

The more conventional TiSi₂ process cannot be easily scaled down to applications with 0.25 μm down to 0.1 μm or smaller transistor gate lengths because the high resistivity C49 (a specific crystallographical configuration of TiSi₂) phase predominates on narrow lines. In contrast, CoSi₂ can be formed on narrow lines without this problem. Nevertheless, the reproducible and reliable formation of thin CoSi₂ on narrow poly-Si transistor gates is still a critical issue.

Recently, CoSi₂ has been introduced in Metal Oxide Semiconductor (MOS) manufacturing. Several CoSi₂ formation processes have been proposed. The deposition of a single layer of cobalt on Si has been replaced by other process sequences because of the difficult manufacturability of this single layer process. Major problems are its sensitivity to cleaning and its irreproducible yield on narrow lines, partly attributed to a silicide thinning effect at the edges of the silicide lines.

U.S. Pat. No. 5,047,367 describes a process for the formation of a titanium (nitride)/cobalt silicide bilayer for use in semiconductor processing. In this patent, it is disclosed that a thin layer of titanium is conformally deposited on a silicon substrate using a sputter deposition technique. A conformal layer of cobalt is next deposited by sputter deposition without removing the substrate from the sputter system. The substrate is then heated. It is believed that during the process, the titanium first cleans the silicon surface of the substrate of any native oxide. During the heating step, the titanium diffuses upward and the cobalt diffuses downward. The cobalt forms a high quality epitaxial cobalt silicide layer on the silicon substrate. This Ti/Co (Ti at interface) metallization scheme has been introduced to alleviate the requirements for cleaning and has been proposed for its epitaxial CoSi₂ growth. The latter feature though results in a CoSi₂ with a relatively high stress. More importantly, the epitaxial CoSi₂ generates a high stress in the adjacent Si and in the Si underneath. Furthermore, the presence of Ti/Si metals at the interface retards the Co/Si reaction.

### SUMMARY OF THE INVENTION

A CoSi₂ salicidation technology based on a deposition sequence of cobalt and nickel or of other alloys of cobalt is provided to further improve the uniformity of as-formed CoSi₂ and as such to further improve the thermal stability of very narrow CoSi₂/Polysilicon stacks and very narrow silicided active areas. The CoSi₂ salicidation technology based on a deposition sequence of cobalt and nickel or of other alloys of cobalt has as further advantages the fact that the heating temperatures and the overall thermal budget of the CoSi₂ salicidation technology can be reduced. This CoSi₂ salicidation technology can be used with a thin capping layer made of titanium or titanium nitride.

Further provided is a salicidation technology of other near noble metal (Ni, Pd, Pt) suicides (NiSi, PtSi, Pd₂Si) and any combination thereof or any combination thereof with cobalt silicides. The silicided polysilicon lines being fabricated according to the invention are very uniform, and can withstand thermal treatments without significant degradation for transistor gate lengths down to 0.08 μm or below. The present invention aims to suggest a method which can be implemented for the self-aligned silicidation in a 0.25 μm CMOS or a 0.18 μm CMOS or a 0.13 μm CMOS process or smaller gate processes such as 0.1 μm or 0.07 μm CMOS processes. The process of the invention has a large process window in terms of silicidation temperature and ambient. This is beneficial for the manufacturability of the process. In a preferred embodiment, the silicide can be polycrystalline and the substrate can be either a monocrystalline or a polycrystalline Si substrate. The substrate has a low stress resulting in low leakage current levels for large area diodes with narrow dimensions.

The salicidation process of the invention has a wide process window to obtain uniform silicide films more reproducibly than conventional salicidation processes. The robustness of the CoSi₂ salicidation technology based on a deposition sequence of alloys of cobalt, a variant of the Co/Ti (cap) process, of the invention makes it very attractive for 0.25 μm CMOS processes or 0.18 μm smaller gate length CMOS processes.

In a first aspect of the present invention, a method of forming a cobalt disilicide, preferably polycrystalline cobalt disilicide, on a silicon substrate is provided, including the steps of depositing a first layer structure including cobalt and nickel on a part of the substrate, the part including a first region capable of undergoing a silicide reaction and a second region incapable of undergoing a silicide reaction, optionally depositing a metal getter layer, e.g., of a refractory metal such as titanium, on the first layer, and heating the silicon substrate in a first heating step, the first heating step being performed at a first temperature being such that the first heating step forms a silicidecobalt on the first region; optionally treating the substrate with at least one chemical solution, the chemical solution selectively removing at least the remaining non-silicidecobalt and/or the getter metal and/or the cobalt-getter or cobalt-nickel getter or nickel-getter metal alloys from the substrate; and thereafter optionally treating the substrate in a second heating step to thereby form the polycrystalline cobalt disilicide layer on the first region of the part of the substrate. This second heating step can be combined with subsequent CMOS processing steps if needed. The second heating step can be performed at a higher temperature than the first heating step.

The first heating step can be executed while or after depositing the first layer structure.

The term cobalt disilicide is to be understood as cobalt disilicide (CoSi₂) or as a cobalt-nickel alloy disilicide (CoₓNiₗ₋ₓSi₂). Cobalt silicide is to be understood as CoSi, cobalt disilicide as CoSi₂, silicide nickel as any product containing silicon and nickel, and nickelsilicide as NiSi.

The deposition of the first layer structure and/or the metal getter layer can be executed at room temperature or at an elevated temperature or even at lower temperature. Deposition at an elevated temperature, for example, would alleviate the need for a separate first heating step as at this temperature already the first transformation to silicidecobalt can take place, depending on the nickel content. The first layer structure can include a first nickel layer deposited on the part of the substrate, followed by a cobalt layer deposited on the nickel layer. The first layer structure can also include a first cobalt layer deposited on the part of the substrate, followed by a nickel layer deposited on the cobalt layer. The first layer structure can also include a sequence of cobalt/nickel layers such as a Co/Ni/Co structure. The Co/Ni layers of the first structure can have different and varying thickness. In a preferred embodiment, the nickel layer has a thickness of from about 0.5 nm to about 50 nm, more preferably about 3 nm, and the cobalt layer has a thickness from about 1 nm to about 40 nm, more preferably about 9 nm. The first layer structure can also include a cobalt-nickel alloy with the nickel content varying from 0 to 100%; preferably the nickel content of the alloy is smaller than 50%, more preferably smaller than 25%, more preferably less than 15%, and can even be less then 10%. Also, other metals such as Pt or Pd can be chosen as elements that are present in the first layer structure. For instance, a layer sequence of Co/Pt/Co can also be envisaged, or the elements Pt and Pd can be added in minor amounts to the first layer structure. Also, other elements such as Au, Ir, Os, Rh, Ti, Ta, W, Mo, Cr, C, and Ge can be part of the first layer structure. The getter layer can be incorporated in the first layer structure as this first layer structure can include an alloy of nickel, cobalt and a getter layer material. In a preferred embodiment, the getter layer comprises a titanium layer having a thickness of less than about 20 nm, more preferably about 8 nm.

The silicon substrate, for example, can be a partially processed wafer in a MOS process. The second part of the silicon substrate can be covered with an oxide (SiO₂).

Silicidecobalt is to be understood as any cobalt-silicon compound CoₓSi_{y} or CoₓNiₗ₋ₓSi_{y}. Preferably, the silicidecobalt is cobalt(nickel)silicide (Co(Ni)Si). A getter layer is to be understood as a capping layer on the top of the first layer that is able to absorb desorption of contaminating species out of the substrate, e.g., out of the second part or out of an oxide in the second part. At the same time, the getter layer has the function of efficiently stopping the penetration of ambient contaminating species into the substrate or into the first layer. The getter layer can be a refractory metal. The getter layer preferably includes Ti. The getter layer can also include C, Ta, W or combinations thereof.

Preferably, during the chemical solution treatment, a passivation layer is grown on top of the silicidecobalt being formed on the first part of the substrate. The passivation layer is a thin layer. A thin layer is a layer having a thickness that has no negative or detrimental impact on the further processing steps being executed with the silicon substrate. The thin layer can be a 5 nanometer (nm) thick SiO₂ layer on the top of the silicidecobalt. Such a chemically grown thin layer protects the silicide during further processing steps. The thermal stability and integrity is achieved by the growth of this chemical oxide during selective etch.

In a second aspect, the present invention is related to a method of forming a polycrystalline cobalt disilicide on a silicon substrate, including the steps of depositing a layer structure on at least a part of the substrate, the layer structure including at least cobalt and nickel and a refractory metal, the part of the substrate having a first region capable of undergoing a silicide reaction and a second region incapable of undergoing a silicide reaction; thereafter heating the silicon substrate on a first heating step, the first heating step being performed at a first temperature being such that the first heating step forms a silicidecobalt on the first part; optionally treating the substrate with at least one chemical solution, the chemical solution selectively etching the remaining non-silicidecobalt and the refractory metal and cobalt refractory metal alloys from the substrate; and thereafter optionally treating the substrate in a second heating step, the second heating step being performed at a higher temperature than the first heating step thereby forming the polycrystalline cobalt disilicide layer on the first region of the part of the substrate. In a preferred embodiment, the first heating step wherein silicidecobalt is formed is conducted at a temperature of about 300° C. to about 700° C. for a time period of from about 10 seconds to about 100 seconds, and the second heating step wherein cobalt disilicide is formed is conducted at a temperature from about 400° C. to about 1000° C. and a time period from about 10 seconds to about 100 seconds. More preferably, the first heating step is conducted at a temperature of about 550° C. for about 30 seconds and the second heating step is conducted at a temperature of about 700° C. for about 30 seconds.

The deposition of the layer structure can be executed at room temperature or at an elevated temperature or even at lower temperature. In a preferred embodiment, the deposition step includes sputter deposition under a vacuum in a vacuum system. If a metal getter layer is also deposited, in a preferred embodiment the layer is also formed by sputter deposition under a vacuum in a vacuum system, and the vacuum is not broken in-between the depositing steps. The layer structure can include a cobalt-nickel-titanium alloy with the contents of the different elements varying from 0 to less than 100%; preferably the nickel content of the alloy is smaller than 50%, more preferably smaller than 25%, or even smaller than 10%. Also, other metals such as Pt or Pd can be chosen as elements that are present in the layer structure. The elements Pt and Pd can be added in minor amounts to the layer structure. Also, other elements such as Au, Ir, Os, Rh, Ti, Ta, W, Mo, Cr, C, and Ge can be part of the layer structure. The different metals can be deposited in consecutive steps in separate chambers or simultaneously, i.e., by using an alloy.

In a preferred embodiment of the present invention, a silicide layer is formed on a transistor. The transistor is formed by defining an active area within the silicon substrate; growing an oxide on at least a portion of the active area of the substrate; depositing a polysilicon layer on the oxide; defining a gate region, a source region, and a drain region within the active area thereby forming a transistor, the gate region, source region and drain region forming a first region of a part of the substrate upon which the silicide is formed.

In yet another aspect of the invention, the formation of other near noble metal silicides (NiSi, Pd₂Si, PtSi) is provided.

### BRIEF DESCRIPTION OF THE DRAWINGS

FIG. 1 shows a flow sheet of a first preferred embodiment of the present invention compared to the state of the art processes, wherein branch I represents a conventional process using only cobalt sputtering, referred to as to be the conventional Co process, branch II describes a sputtering conventional Ti/Co process, and branch III represents the capping Co/Ti process according to the present invention.

FIG. 2 represents the schematic views of the devices obtained according to the several steps performed according to the capping Co/Ti process as described in branch III of FIG. 1.

FIG. 3 represents data concerning the growth of a chemical oxide.

FIG. 4 shows the sheet resistance as a function of a first RTP temperature for the conventional Co process and the capping Co/Ti process according to the present invention.

FIG. 5 shows the sheet resistance after RTP1, RTP1/SE and RTP1/SE/RTP2 for a 15 nm thick Co film with a 8 nm Ti cap. RTP1 was varied while RTP2 temperature was held constant at 700° C. (SE=selective etch).

FIG. 6 shows Raman shift versus silicide thickness for silicided lines with 3 μm linewidth and 3 μm spacing for various silicides. The stress in the Si in-between the silicided lines is proportional to the Δω value.

FIG. 7 represents oxygen concentration in the N₂ ambient during RTP for a Si dummy wafer, a wafer with Co, a wafer with Co/Ti (cap) and a wafer with Co/TiN (cap).

FIG. 8 represents the electrically measured linewidth as a function of an optically measured linewidth for the three processes described in branch I (FIG. 6a), branch II (FIG. 6b), branch III (FIG. 6c) of FIG. 1.

FIGS. 9, 10, and 11 represent the cumulative probability of the sheet resistance of different gate widths for the three processes described in branch I, branch II, and III of FIG. 1 in the case of As-formed film (FIGS. 9a, 10a, and 11a, respectively) and in the case after a heat treatment consisting in a 750° C., 30 min furnace annealing (FIGS. 9b, 10b, and 11b, respectively).

FIG. 12 represents sheet resistance for 150 μm BF₂ doped poly runners of various linewidths.

FIGS. 13 and 14 represent electrical linewidth measurements on unsilicided/silicided poly runners.

FIG. 15 represents sheet resistance of 0.25 μm polylines at various lengths.

FIG. 16 represents a possible flow sheet of silicide formation.

FIG. 17 represents the cumulative probability of the sheet resistance for the conventional Co only process as formed (FIG. 17a) and after a heat treatment consisting of 700° C. and 30 minutes furnace heating (FIG. 17b).

FIG. 18 represents the cumulative probability of the sheet resistance for the Co/Ti cap process according to the present invention, as formed (FIG. 18a) and after 700° C. and 30 minutes furnace heating (FIG. 18b).

FIG. 19 represents sheet resistances versus temperature for the conventional Co process, the Co/Ti cap process and the Co-alloy(Ni)/Ti cap process of the best mode embodiment of the invention.

FIG. 20 calculates silicon consumption versus sheet resistance for CoSi2 and NiSi.

FIG. 21 shows sheet resistance versus poly linewidth in the case of an 18 nm/8 nm Ni/Ti bilayer. RTP was done at 450° C. for 30 s.

FIG. 22 shows sheet resistance versus poly linewidth in the case of an 18 nm Ni bilayer. RTP was done at 450° C. for 30 s.

FIG. 23 shows sheet resistance (a) and standard deviation (b) versus temperature for narrow BF₂-doped polysilicon lines after Ni-silicidation.

FIG. 24 shows transformation curves of NiSi (12 nm or 18 nm) both with and without an 8 nm Ti-cap layer.

### DETAILED DESCRIPTION OF THE PREFERRED EMBODIMENT

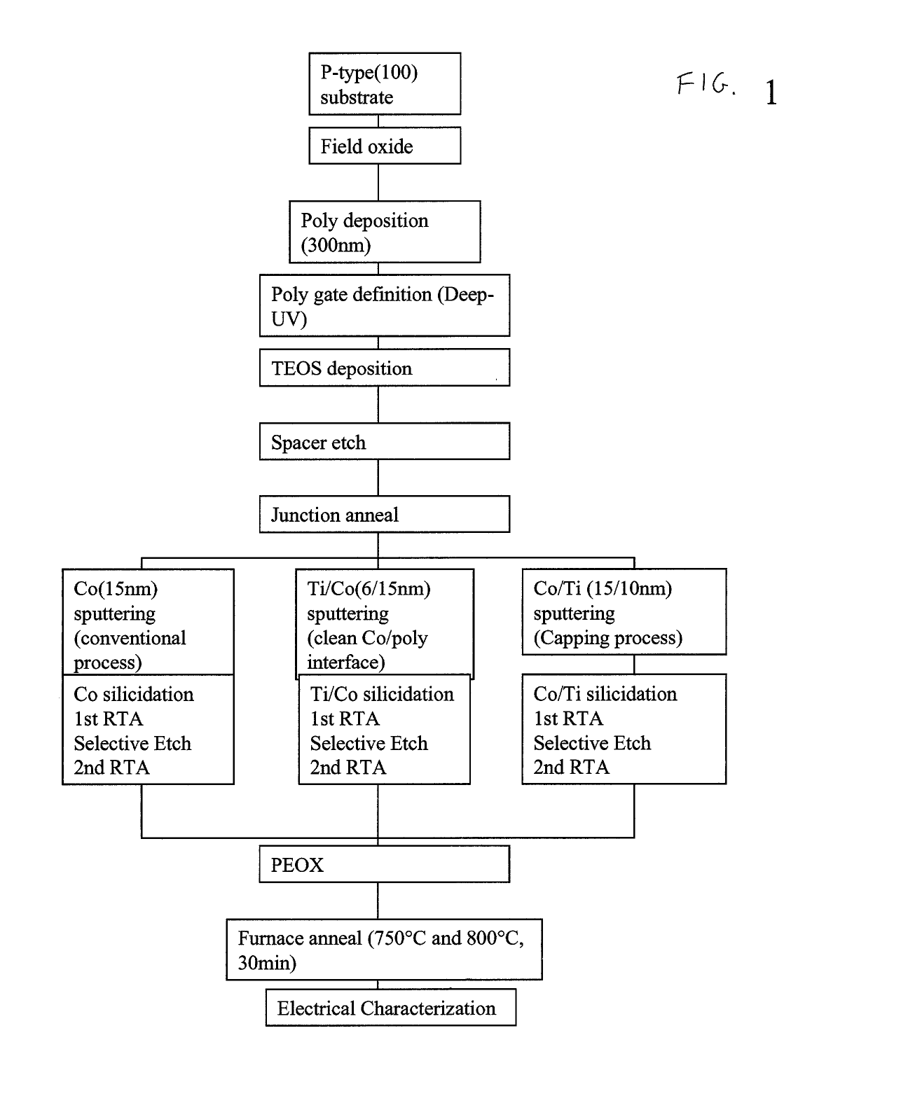

A first embodiment of the present invention is shown in FIG. 1, wherein a comparison is made with prior art processes. The major steps of transistor gate formation for a 0.25 μm CMOS process are simulated.

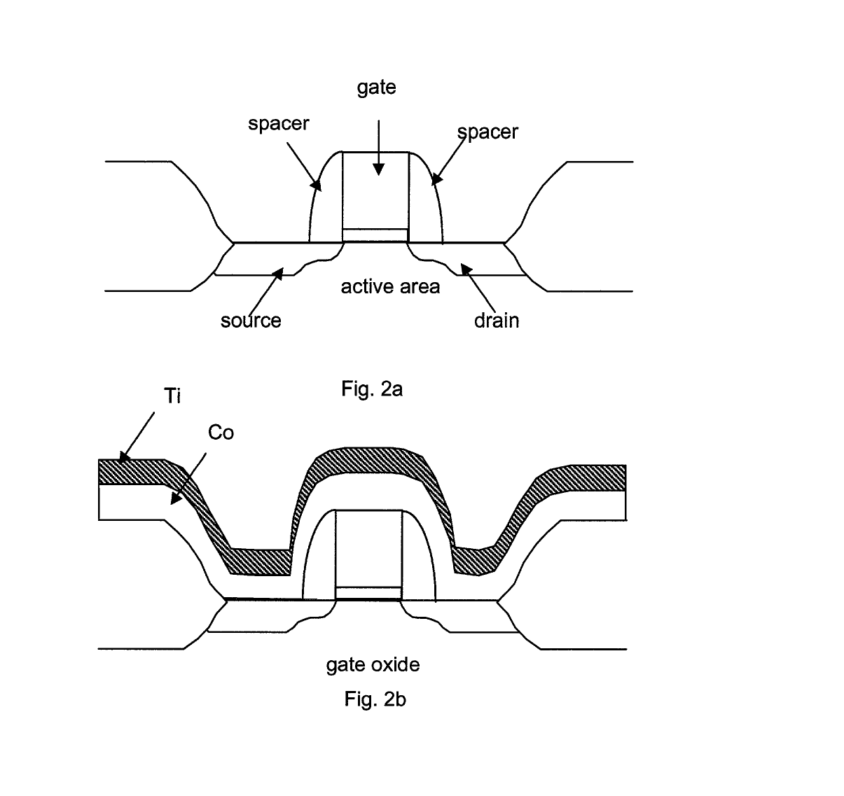

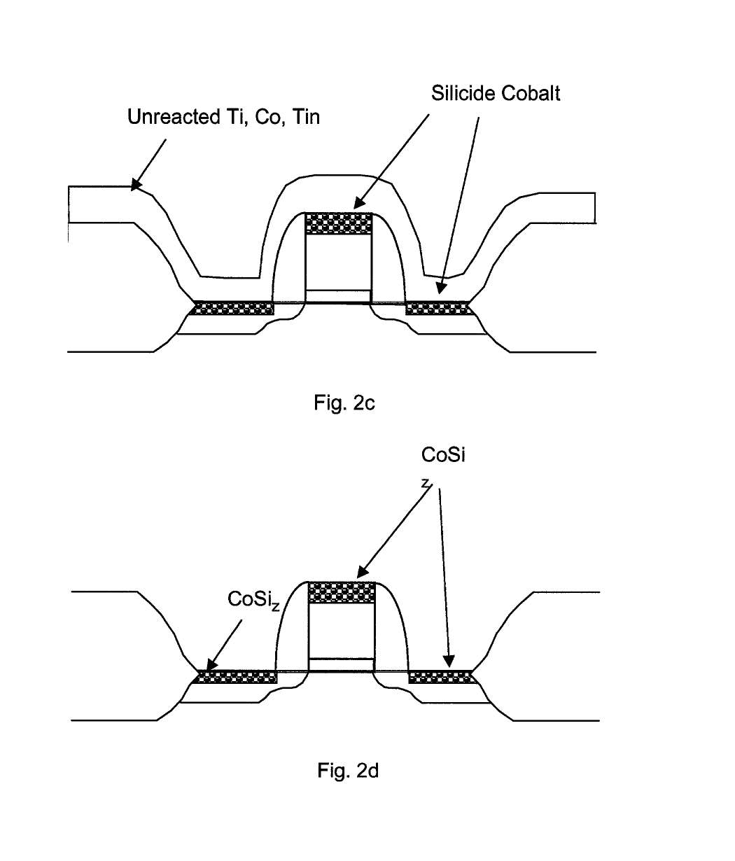

The device structures obtained after performing each step of the process according to the present invention are represented in FIG. 2.

The starting wafers can be (100) oriented, p-type silicon wafers (see FIG. 2a). An experimental description follows.

After an RCA-type cleaning in NH₄OH/H₂O₂, HC1/H₂O₂, and BHF, a 350 nm thermal oxide is grown. A 300 nm polysilicon layer is then deposited. It should be understood that the thickness of 350 nm for the oxide layer and the thickness of 300 nm for the polysilicon layer are only illustrative numbers which refer to the described experiment. Typically, silicon wafers are taken that have already been processed with an isolation module, polypatterning, spacer formation and source, drain and gate doping. Similar results, as the one disclosed in the sequel, can be obtained on such processed wafers with thin (e.g., 2-10 nm) gate oxide layers and with, e.g., 100-250 nm polysilicon layers.

In this first experimental embodiment, deep UV lithography was used to define 0.25 μm poly lines. Other lithography techniques could be used as well prior to silicidation. The wafers are dipped in diluted HF to remove a native oxide layer, just prior to loading into a sputter vacuum deposition system. Three process conditions are used:

Branch I

15 nm cobalt film sputtering, which is called the conventional Co process.

Branch II

6 nm titanium film followed by a 15 nm cobalt film sputtering, which is referred to as the conventional Ti/Co process,

Branch III

15 nm cobalt film followed by 10 nm titanium film sputtering, which is referred as the Co/Ti cap or capping process according to the present invention. It can be executed with cobalt layer thicknesses ranging between 5 and 50 nm and titanium layer thicknesses ranging between 1 and 20 nm (FIG. 2b).

The cobalt and Ti layers are preferentially sputtered sequentially in a vacuum system without breaking the vacuum conditions in-between subsequent deposition steps. Sputtering can be done on heated or non-heated chucks. For the conventional Co scheme, a standard heating using a two step RTP silicidation is employed (the first RTP at 550° C. for 30 s, and the second RTP at 700° C. for 30 s), while for the capping process a slightly modified heating process is used: the first RTP preferentially at 550° C. for 60 s, and the second RTP preferentially at 700° C. for 30 s. The first RTP step can be executed within a range of 450° C. to 600° C. with the heating time ranging between 10 and 100 seconds, the second RTP being performed within a range of 600-1000° C. with the heating time ranging between 10 and 100 seconds. All the RTP's are performed in an AST SHS 2000 model.

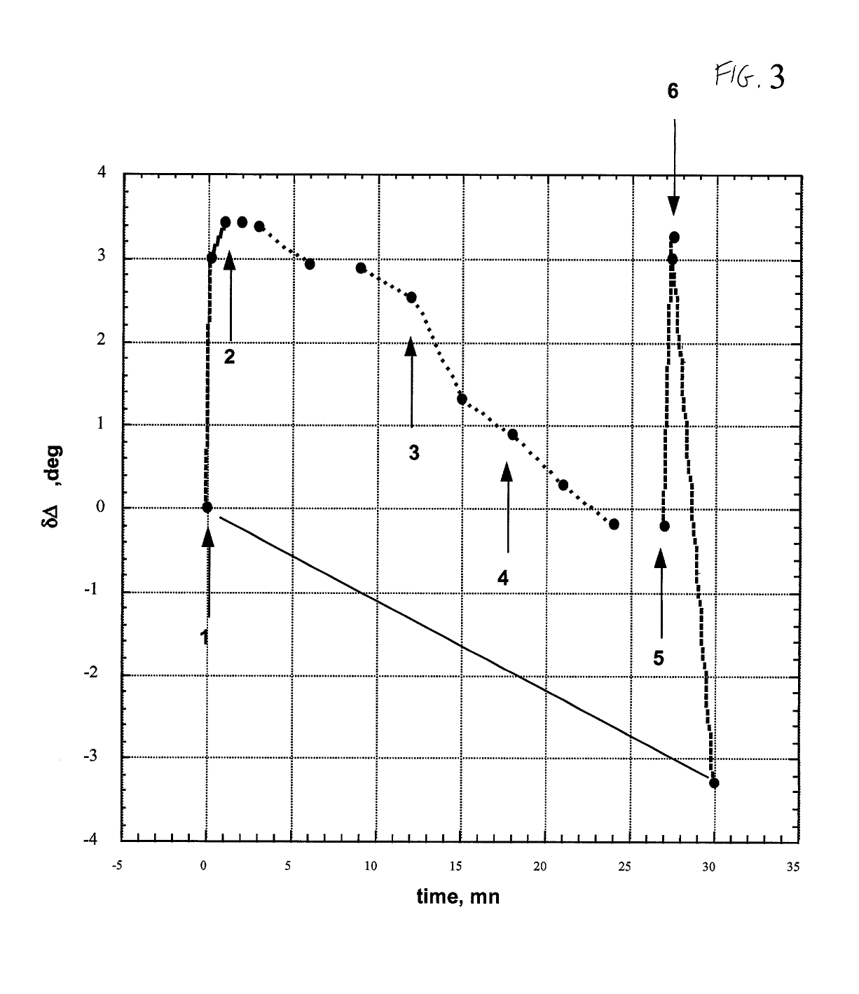

A selective etching is performed between the first and the second RTP steps. The remaining metals or metal alloys (Co/Ti/TiN not being transformed to silicidecobalt) after heating are selectively etched using a H₂SO₄ solution and/or a NH₄OH solution as etchants or using another solution (e.g., comprising H₃PO₄) functioning as such a selective etchant. In a preferred embodiment, the etchant solutions are H₂SO₄:H₂O₂ mixture in [4:1] ratio being applied for 10 min at 90° C. and a NH₄OH:H₂O₂:H₂O mixture in [1:1:5] ratio being applied at 50° C. for 100 seconds. The application times can be varied, the application temperatures can be varied as well. In the preferred embodiment, the two etchant solutions are applied as a two-step process. The ammonia solution takes away the polluted titanium(TiON) and cobalt which form during the RTP treatment. The sulfuric acid is there to take away remnants of cobalt on the non-silicided areas but even more to grow a thin SiO₂ layer on top of the CoSiₓ. This chemically grown passivation layer protects the silicide during further processing. This is especially beneficial for the scalability towards narrower dimensions. FIG. 3 shows ellipsometry measurements indicating the chemical growth of an oxide layer during immersion of a silicidecobalt in H₂SO₄—H₂O₂ mixture (indicated by points 5 and 6 on the graph). The formation of SiO₂ was confirmed by XPS. The layer grown is on the order of 5 nm thick. This thin oxide serves as a controlled passivation layer for further processing, for instance, during the second heating step that is, e.g., executed at a higher temperature than the first heating step. This thin oxide layer allows the process of the invention to yield a highly stable (thermally stable) and integer (not sensitive to contamination) cobalt disilicide after growth. This thin oxide can be grown thicker in the second RTP step by allowing some O₂ in the ambient of the RTP furnace.

The structure obtained according to the described process is self-aligned.

The wafers made according to this first embodiment are analyzed by four point probe, by scanning electron microscope (SEM) and by electrical linewidth measurements. Data are collected from approximately 80 structures across the wafer (FIG. 2d).

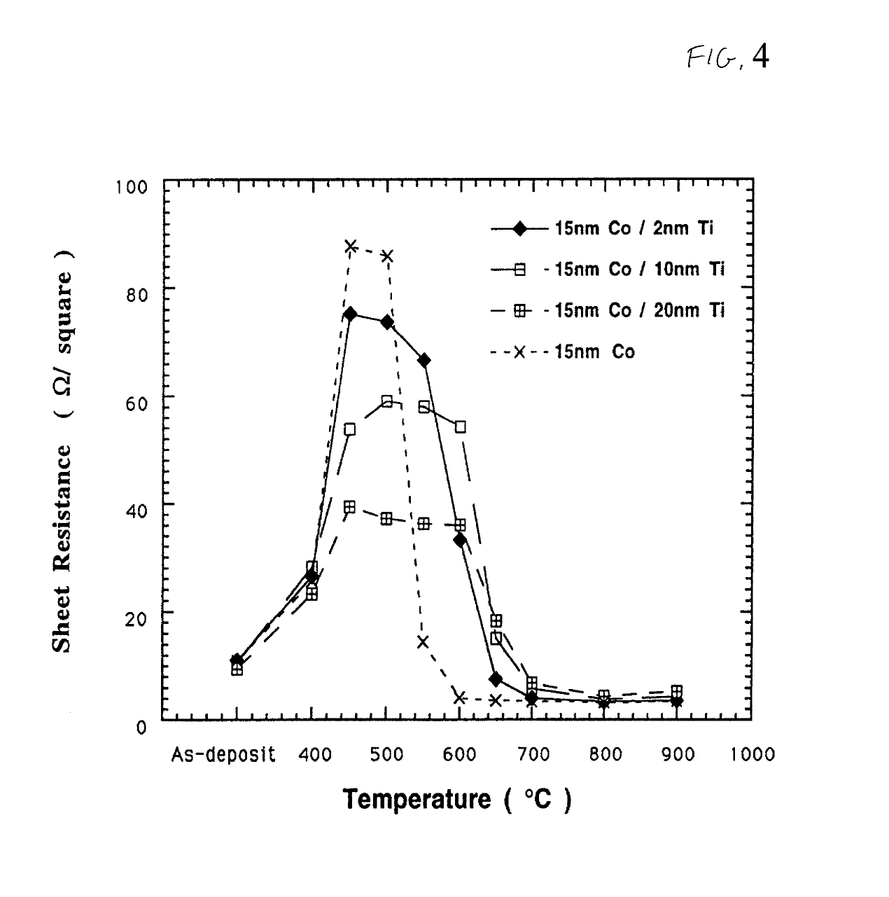

To investigate the effect of titanium capping, capping layers with various thicknesses were used. FIG. 4 depicts the sheet resistance as a function of first RTP temperature for the Co/Ti cap process compared to the conventional cobalt process. The sheet resistance is measured without removal of either the unreacted cobalt or the titanium(and/or TiN, TiN being formed by the reaction of Ti with N present in the RTP chamber). The sheet resistances first go up at the same temperature (400° C.), and then go down at temperatures from 550° C. to 650° C., depending on the process conditions. This can be explained by the silicide phase transformation sequence:

Co->Co₂Si->CoSi->CoSi₂

The data confirm that the titanium capping layer does not significantly affect the CoSi formation within the temperature resolution of the experiment but retards the formation of CoSi₂.

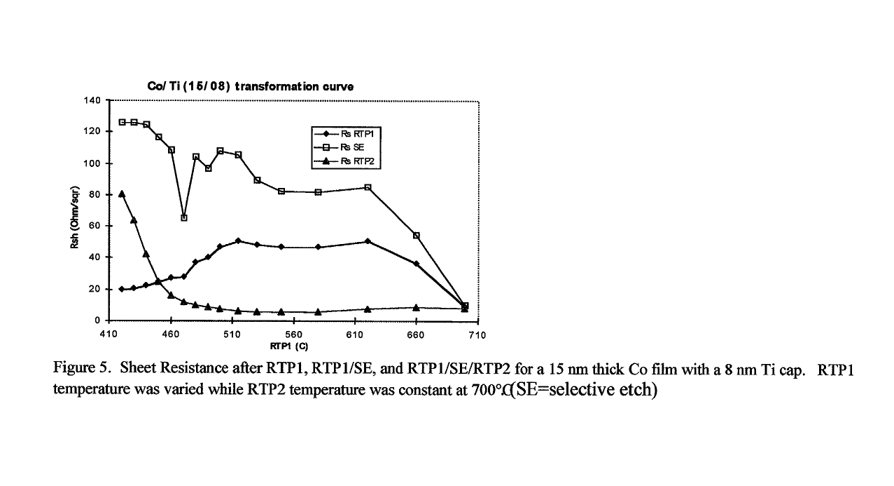

The sheet resistance versus RTP1 temperature for the Co/Ti (cap) salicidation is shown for a 15 nm cobalt film with a 8 nm Ti cap in FIG. 5 with more wafers at the various temperature. As compared to the Ti/Co (Ti at interface) process, the transformation temperature for Co->CoSi transformation is reduced, and the temperature for the formation of CoSi₂ during RTP1 is increased. The specific separate phase transitions occur in a narrow temperature window. This creates a broad processing temperature window for RTP1 in which CoSi is the stable phase. The silicide thickness is independent of RTP1 temperature between 510° C. and 600° C. The resistivity of the CoSi equals 182 μOhm-cm and the resistivity of the CoSi₂ is 18 μOhm-cm.

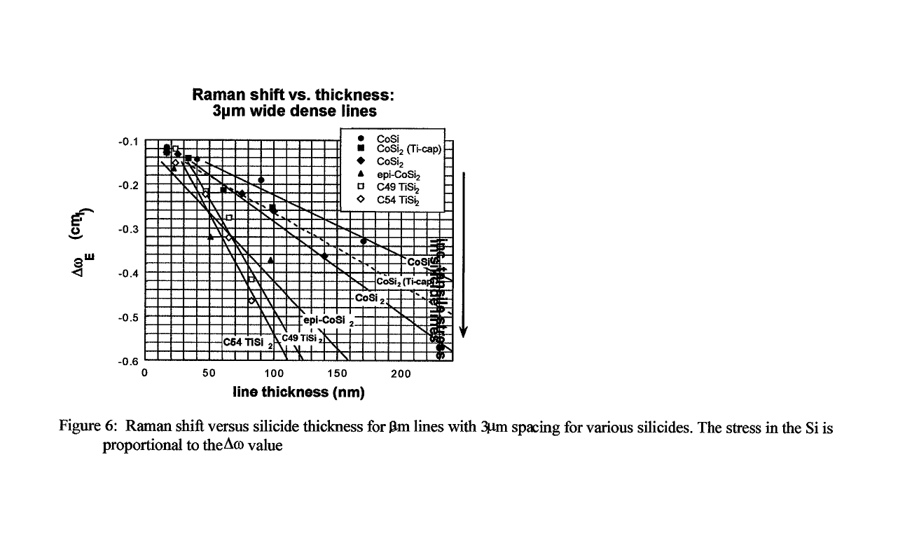

The formed CoSi₂ film is polycrystalline. This is essential in view of the stress build-up in the underlying Si. FIG. 6 shows the stress in the Si generated by the CoSi₂. The stress is low in the case of the Co/Ti (cap) process as compared to the Ti/Co (Ti at interface). Due to the polycrystalline nature of the CoSi₂ formed by the Co/Ti (cap) process, the stress build up is only due to a difference in thermal expansion coefficient in contrast to the epitaxial alignment as in the case of the Ti/Co (Ti at interface).

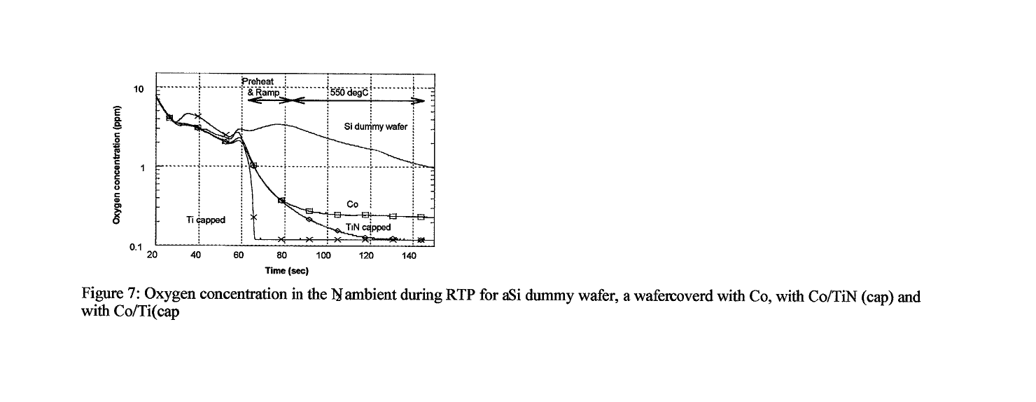

The role of the Ti cap layer in the Co-silicidation process is studied by monitoring the ambient during RTP 1. The main species of interest are the evolution of the O₂ content in the ambient, the H₂O content and the CO₂ content. It is important to notice that the wafer itself plays an active role by adsorbing and desorbing these species during processing. The O₂ level during Co silicidation (RTP1) is depicted in FIG. 7. Whereas the steady O₂ level of state of the art RTP systems is less than 1 ppm, if sufficient time is reserved for purging, the Ti cap layer causes a drop in the O₂ level below 0.1 ppm (measurement limit). The chemical activity of the Ti is essential. A TiN cap is far less efficient. Thus Ti is an efficient getter layer.

Similar measurements are made for CO₂ and H₂O. CO₂ adsorbs significantly more on Co than on a Ti or TiN cap. Both Ti and TiN capping layers are efficient in stopping the outgassing of H₂O. It should be noted, however, that H₂O will be captured by the Ti. TiN can not play that role, as shown in the reference M. Yoshimaru et al., IEEE 1995. For adsorbed species on the wafer, the diffusion barrier properties of the TiN are a drawback as compared to the chemical activity of the Ti layer. Therefore the presence of adsorbed H₂O can lead to thinning effects in the case of a TiN cap along SiO₂ edges.

The getter layer is able to absorb desorption of contaminating species out of the substrate, e.g., out of the second part or out of an oxide in the second part. At the same time, the getter layer has the function of efficiently stopping the penetration of ambient contaminating species into the substrate or into the first layer. The getter layer preferably comprises Ti and can also comprise TiN, C, Ta, W, and combinations thereof. The getter layer can be a separate layer or its compounds can be added to the nickel layer, preferably when the nickel is deposited on top of the cobalt layer. For example Ti can be added to Ni in the form of a 5% Ti/Ni alloy deposition. If the process temperature of the RTP steps can be decreased low enough to avoid outgassing, then the getter layer can be left out.

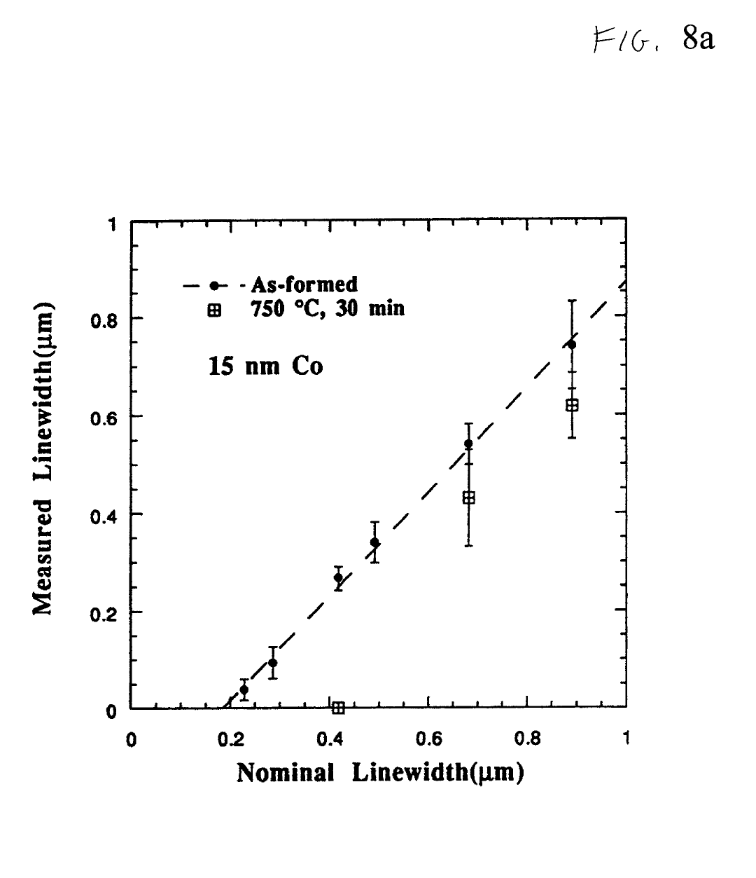

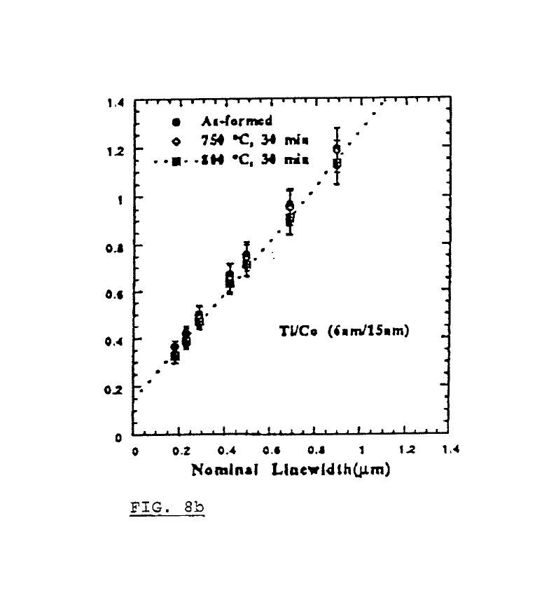

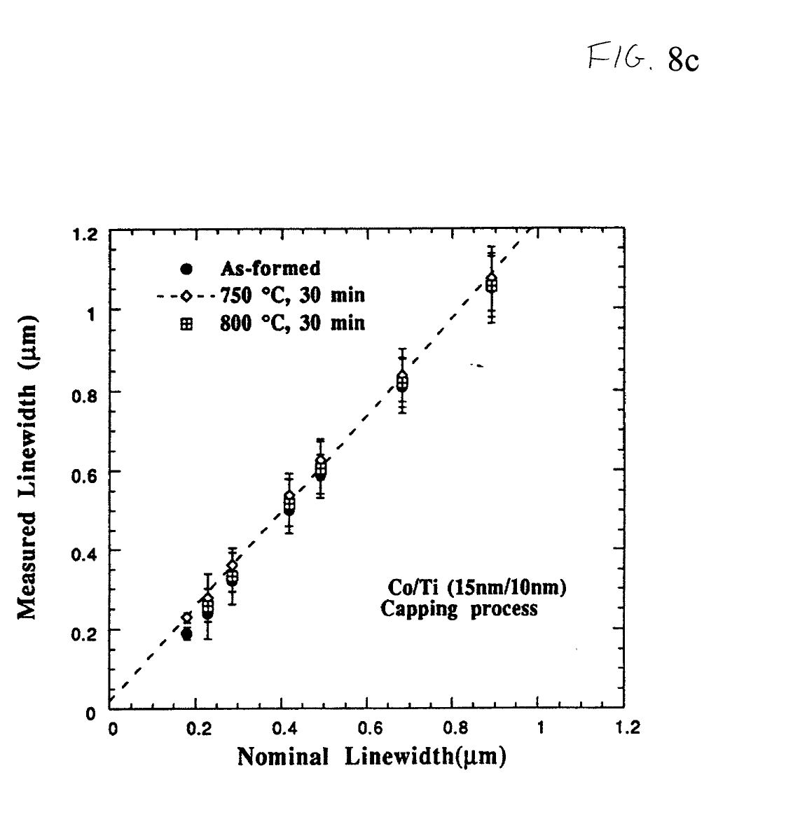

FIGS. 8a, 8b, and 8c depict the electrically measured linewidth versus optically measured linewidth for the conventional cobalt process, for the conventional Ti/Co process, and for the capping Co/Ti process of the invention. The linewidth is obtained based on the following formula:

W=L(I/V)×R_{vdp}

where L is the length of the bridge resistor, I is the forced current, V is the measured voltage drop, and R_{vdp} is the sheet resistance measured from van der Pauw structure.

Comparing FIGS. 8b and 8c, one can find that even for the as-formed case the conventional process gives a strong apparent linewidth loss, which is believed to result from non-uniform silicide formation. The as-formed lines using the Co/Ti cap process show the good characteristics. The result is even more prominent after back end processing. After 750° C. furnace anneal for 30 min, the cap process does not give a notable degradation of the sheet resistance of the lines. The conventional process, however, yields a significant increase in sheet resistance (decrease in linewidth) for the narrowest lines for the same 750° C. anneal.

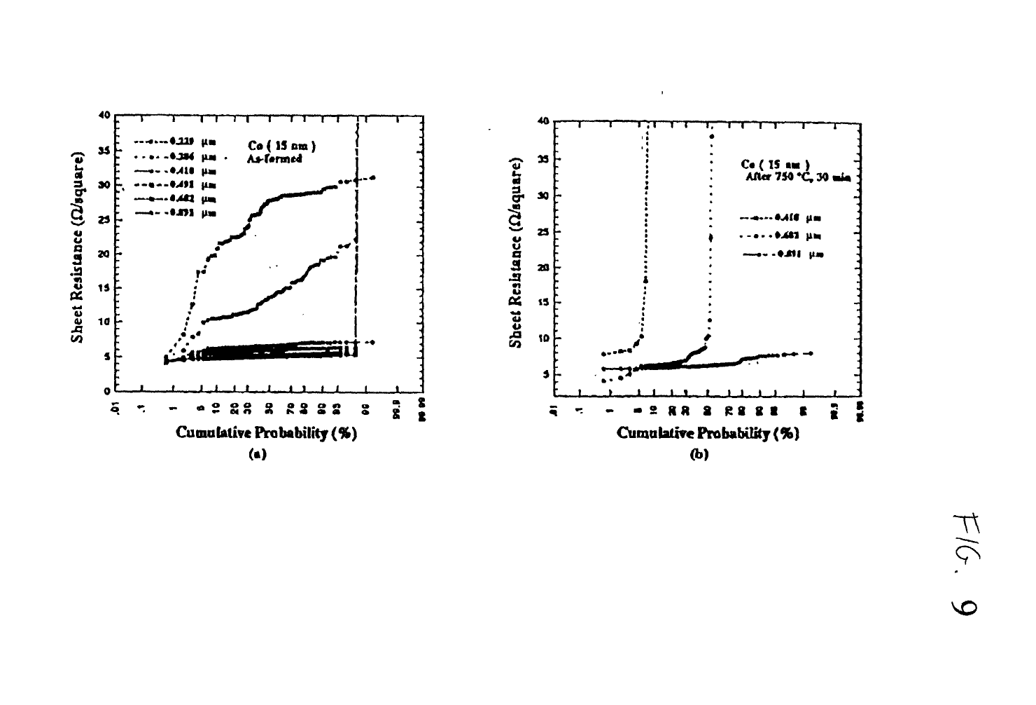

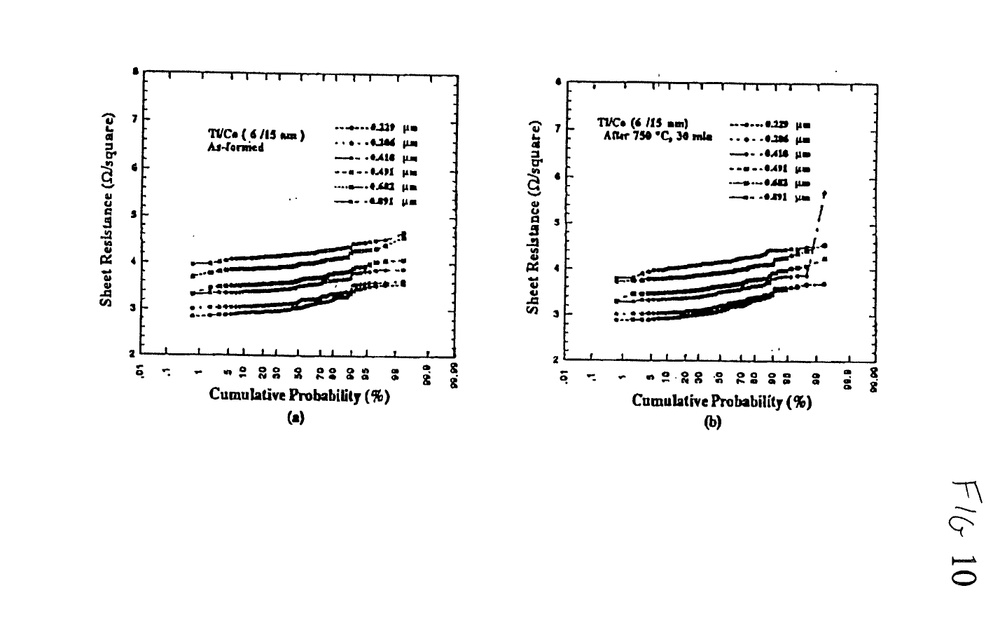

FIGS. 9, 10, and 11 give the statistical data of sheet resistance for different linewidths for the conventional Co process (FIGS. 9a and 9b), for the conventional Ti/Co process (FIGS. 10a and 10b) as well as for Co/Ti cap process (FIG. 11a and 11b) respectively.

Carefully examining FIGS. 9 and 10, one can find that thin CoSi₂ is not uniformly formed on the narrowest lines. For lines narrower than 0.3 μm, there is a large spread in the distribution. After a 750° C., 30 min furnace anneal, only the widest lines show good thermal activity. In contrast, the Co/Ti cap process (FIG. 11a) results in very tight sheet resistance distribution for all defined lines. After a 750° C., 30 min furnace anneal, no significant sheet resistance changes were observed (FIG. 9b). A very tight data distribution is observed for both as-formed and heat treated films when the capping process is employed. The thermal stability improvement is due to the uniformity improvement of the silicide as formed on the narrow lines. Therefore, for thicker films and wider lines, this effect is not as pronounced.

According to this embodiment of the invention, diodes have been fabricated with the Co/Ti (cap) process. Typical leakage currents are <10⁻⁸ A/cm² for large square diodes, and 10²⁻¹¹ A/cm perimeter leakage on long meander diodes. Due to the low stress induced by the silicide in the underlying Si, the formation of dislocations is avoided resulting in low leakage currents.

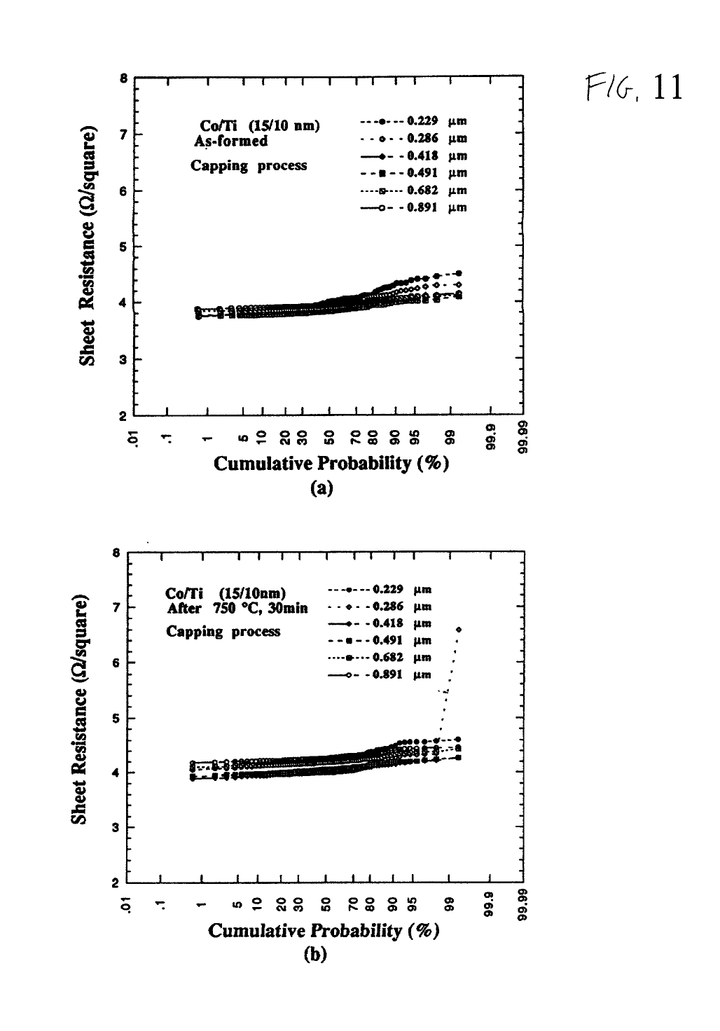

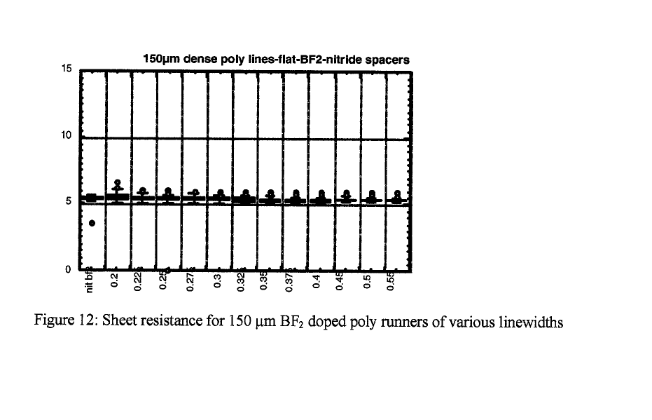

FIG. 12 represents, according to the first embodiment of the present invention, electrical data of the Co-silicide process with Ti cap (the Co/Ti process) on BF₂ doped 150 μm long poly runners with nitride spacers. The runners were patterned by state of the art DUV litho. All measurements of all chips are presented. There is no linewidth dependence. The yield of the narrow lines is very high. Similar results are obtained with oxide spacers and for As doping.

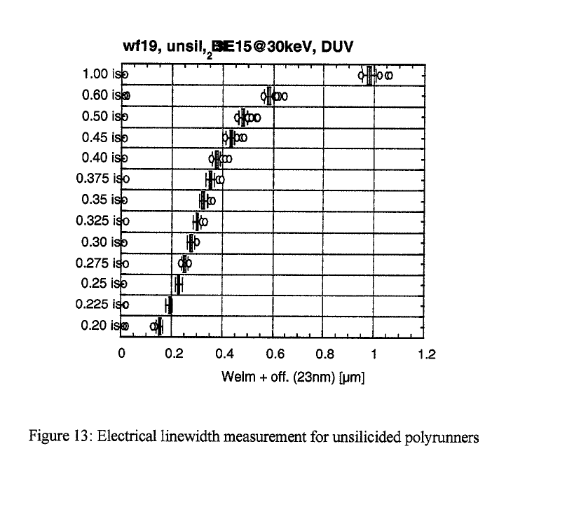

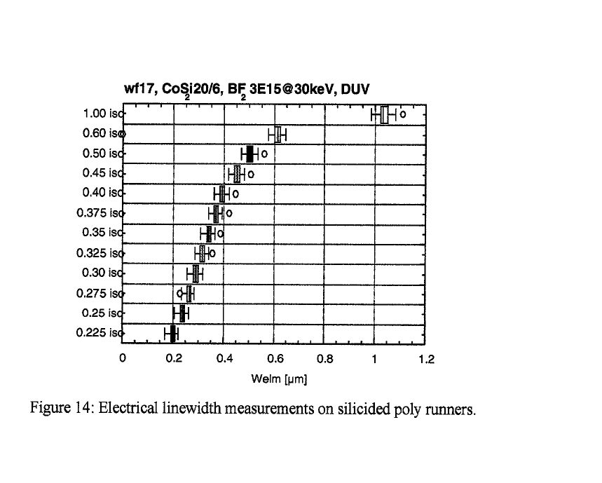

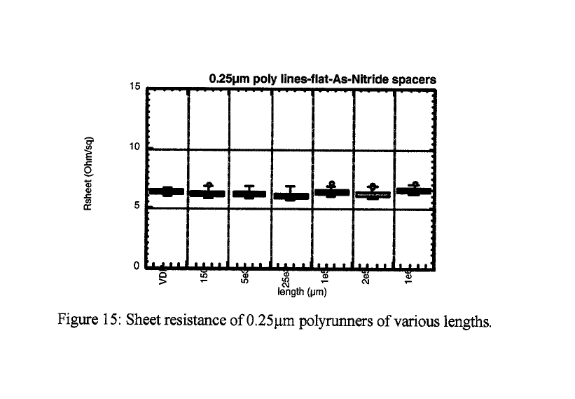

Extensive electrical linewidth measurements were performed on the poly runners in order to nail down any process related non-uniformity. FIGS. 13 and 14 compare the electrical linewidth measurements of non-silicided and silicided lines. The electrical linewidth was measured from the ratio of the narrow line resistance and large Van Der Pauw structures for the various linewidths. Detailed inspection of the data shows that the silicidation process hardly contributes to the spread of the data. Indeed the small variations over the wafers reflect the variations of patterning. It means that the non-uniformities that are expected as a result of RTP do not affect the uniformity of the process. This is an important consequence of the large RTP1 process window of the Co/Ti cap process. FIG. 15 shows performance of the silicide module for very long poly meanders of 0.25 μm width.

In another embodiment of the silicide formation process of the invention for a 0.25 μm CMOS process the following description is given. Typically, silicon wafers are taken that have already been processed with an isolation module, polypatterning spacer formation and source, drain and gate doping. One should start with a wet etch of remaining oxides on the wafer part that is to be silicided. Such oxides can be the implantation oxide and TEOS, the wet etch to be done in a solution (H₂O) of 2% HF for 80 seconds. Thereafter and foregoing loading of the silicon wafer in the deposition chamber (Endura Applied), a 20 second dip in a solution (H₂O) of 2% HF is performed. Alternatively, a sputter cleaning in the deposition chamber can be applied. Thereafter, a deposition of 15 nm cobalt with 8 nm titanium capping layer is performed in the deposition chamber (Endura Applied). The Co-silicidation is performed with a RTP1 step at 550° C. during 60 seconds in a N₂ ambient, followed by a selective etch of 90 seconds in a NH₄OH/H₂O₂/H₂O solution (1/1/5) at 50° C. followed by a 10 minute H₂SO₄/H₂O₂ solution (4/1) at 90° C. The RTP2 step is performed at 700° C. for 30 seconds in a N₂ ambient.

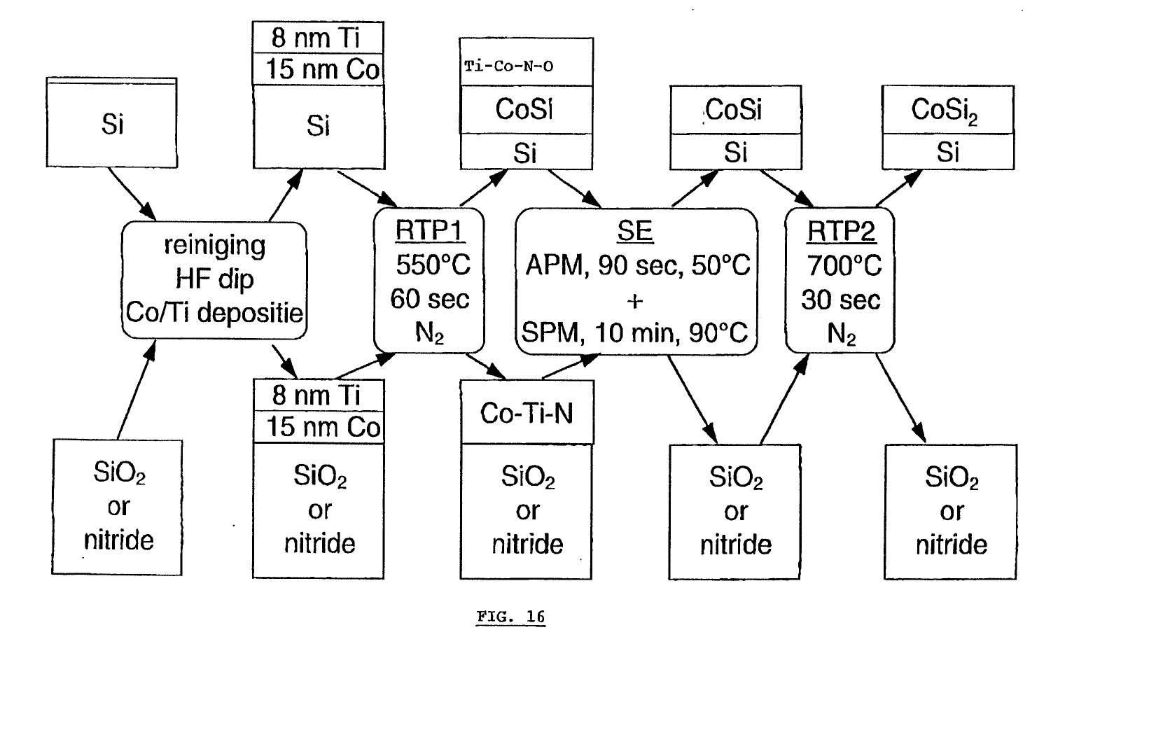

FIG. 16 represents a flowsheet of salicide formation on a silicon wafer according to this best mode example.

According to another preferred embodiment of the present invention for a 0.1 μm CMOS process, the formation of contacts on 0.08 μm (micrometer) polysilicon gates on a MOS transistor using the CoSi₂ salicide process according to the present invention is described in the sequel. The experiments do not show any counter evidence that the process cannot be extended to smaller gate lengths, such as 0.07 μm or 0.05 μm or even smaller gate lengths. The process as described in the second embodiment of the present invention has been successfully implemented in a 0.1 μm CMOS development work on a pilot CMOS line.

The silicon substrates used in the second preferred embodiment are (100) oriented, 5 inch device wafers. After a modified clean, a thin gate oxide (3-10 nm) and a polysilicon layer of 200 nm thickness were deposited. The test patterns are defined with direct e-beam lithography, followed by RIE etching of polysilicon. Both TEOS spacer (100 nm) and nitride spacer (150 nm) were investigated. S/D formation was done by As (NMOS) and BF₂ (PMOS) implantation, respectively. Two process conditions were used: (1) 15 nm Co films, which is the conventional Co process; (2) 15 nm Co followed by 10 nm Ti films, which is referred to the capping Co/Ti process.

A two-step RTP silicidation process was employed. Furnace heating at 700° C. for 30 min was chosen to evaluate the thermal stability of the films. The remaining metal (Co, Ti, TiN) after heating is selectively etched using H₂SO₄ and NH₄OH solutions as etchants. Thus, the structure formed by this process is self-aligned. Electrical measurements were performed with an average of 49 points across the wafers. The wafers were also analyzed by plan-view and cross-section SEM after full electrical characterization.

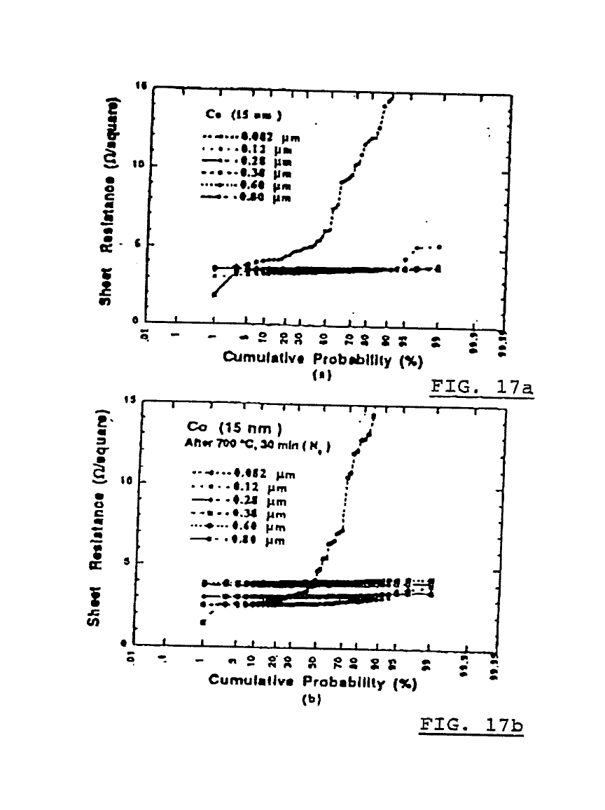

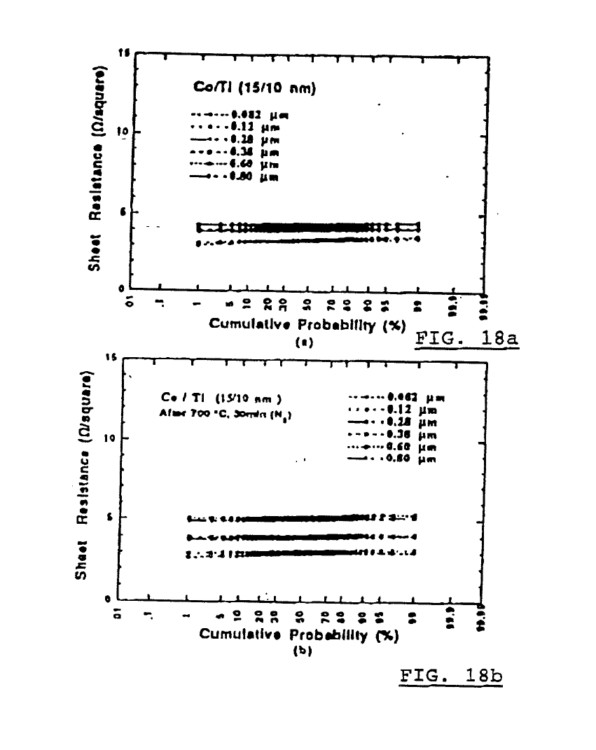

FIGS. 17 and 18 give the statistical data of sheet resistance for both Co and Co/Ti processes with different linewidths. Important observations can be obtained. First, a very tight data distribution is observed for all measured lines when Co/Ti process is employed (FIG. 18a). Second, it is difficult to form thin CoSi₂ on sub-0.1 μm poly-Si runner using the conventional process (FIG. 17a). Third, no significant sheet resistance change was observed after moderate temperature furnace anneal. In a best mode embodiment of the present invention, a Co-alloy(Ni)/Ti cap process is disclosed. Observations on the Co/Ti(cap) process as basis of the silicidation module in an integrated CMOS process show that the temperature of the second heating step will need to be higher for scaling of the Co/Ti(cap) process to smaller gate length geometries. As a result, the process window for the second heating step (RTP2) can be closing down and this may constitute a possible scaling limit for future process developments of the silicidation module. One reason for this may be that the CoSi to CoSi2 transformation is deferred to higher temperatures for thicker Ti capping layers, or thinner Co layers. This occurs even in the case where CoSi has been formed in the first heating step (RTP1) and the Ti-related cap has been removed by selective etch. Even after removal of the cap layer, the CoSi—CoSi2 transition is delayed, probably by incorporation of Ti in the CoSi. Typical temperature shifts that can be observed are of the order of 100° C. (e.g., a transition temperature of 550° C. without Ti, and 650° C. with a 10 nm Ti cap on top of 10 nm Co). Another possible reason may lie in the additional observation that the effect of CoSi2 formation on shallow junction structures yields leaky junctions for lower RTP2 temperatures and better junction quality for higher RTP2 temperatures.

These two phenomena may be linked and related to an incomplete CoSi2 formation at lower RTP2 or an incomplete recrystallization.

The above-mentioned disadvantages of the Co/Ti(cap) process are further explained as follows. For complete CoSi2 formation from an initial Co/Ti layer structure, high RTP2 temperatures are needed. Probably, the higher these RTP2 temperatures are, the higher is the quality of the junction structures and the lower is the resistivity of the silicidized areas. There is, however, a limited process window for high temperature RTP2, since the higher temperatures tend to break up the thin CoSi2 films, especially on the narrowest silicided areas on top of poly-Si. Also, too high RTP 2 temperatures would have a negative impact on the shallow dopant profiles. As a result, the process window for the formation of CoSi2 from an initial Co/Ti layer structure will become too narrow for thinner CoSi2 layers. In non-critical technologies or technologies with larger geometries the second heating or RTP step can be left out, if the resistance of the CoSi is acceptable for the electrical performance of the device.

Therefore, in a best mode embodiment of the present invention, a Co-alloy(Ni)/Ti cap process is disclosed. The Co-alloy(Ni)/Ti cap process builds further on the features and teaching of the Co/Ti (cap) process given in the previous embodiments. In order to overcome the limitations of the Co/Ti (cap) process, the nucleation of CoSi2 can be influenced by either influencing the formation enthalpy, by influencing the entropy of mixing, or by changing the surface energy terms. The entropy of mixing can be influenced by adding some foreign elements to the CoSi and/or CoSi2 phase. The activation energy for nucleation will be decreased the most if the element is insoluble in CoSi and soluble in CoSi2. Table I lists an overview of some elements and their solubility in the cobalt-silicide phases.

TABLE 1
Overview of elements that are expected to be (in)soluble in CoSi/CoSi2

| | |
|---|---|
| Soluble in Co₂Si | Ni, Ru, Rh, Ir |
| Soluble in CoSi | Ge, Fe, Cr, Mn, Ru, Rh, Re, Os |
| Soluble in CoSi₂ | Ni, Au |
| Not miscible with CoSi and CoSi₂ | Sc, Ti, Cu, Y, Zr, Nb, Pd, Hf, Ta, W, |
| | Pt |

One of the elements that is insoluble in CoSi and soluble in CoSi₂ is Ni. NiSi₂ and CoSi₂ both have the CaF₂ structure and are completely miscible. Thus in order to reduce the temperature of the RTP2 heating step, Co should be alloyed with another element such as Ni or Co should be interlayered by this other element either by a layer on the bottom of the Co or on top of the Co (in between the Co and the Ti). The alloy concentration of Ni in the CoNi-alloy can be on the order of 50%, less then 25%, less then 15%, less then 10%, or even 1%; the thickness ratios of the Co and Ni layers can be of the same order. The increased nucleation of the CoSi₂ at lower temperatures results in a reduction of the temperature of the RTP2 heating step. A lower nucleation temperature results in a lower temperature for a smooth interface formation. This is important for the process window of the Co-alloy(Ni)/Ti cap process to reduce the leakage current for shallow junctions.

Several modes of executing the Co-alloy(Ni)/Ti cap process according to the best mode embodiment of the invention can be envisaged. The process flow given above for the Co/Ti (cap) process can be applied to this Co-alloy(Ni)/Ti cap process. In addition to the above teaching, the following process steps can be executed: Ni can be added to the Co layer by using an alloyed target; a Ni layer can be deposited at the interface between Co and Si; a Ni layer can be deposited in-between two Co layers; or a Ni layer can be deposited in-between the Co and the Ti layer.

An exemplary process flow according to the best mode of the invention is as follows. A layer structure of 3 nm Ni/9 nm Co/8 nm Ti is deposited on a silicon substrate by sputter deposition in a PVD Endura tool of Applied Materials. The deposition in the vacuum system is done without breaking the vacuum in-between subsequent deposition steps. This structure is heated in a first heating step at 550° C. for 30 seconds. The structure is heated in a second heating step at 700° C. for 30 seconds. In between the heating steps, a selective etch in a mixture of NH₄OH:H₂O₂:H₂O and H₂SO₄:H₂O is executed. Details of the selective etching process are given in the embodiments above. The Ni layer thickness can vary from 0.5 to 10 nm; the Co layer thickness can vary from 5 nm to 20 nm. The thickness of the Ti layer can also be about 2 nm. The thickness of the Ti capping layer can be below 50 nm, more preferably below 20 nm.

The presence of Ni accelerates the formation of the disilicide phase. For a Ni interlayer between Co and Si, the disilicide phase already forms at 400° C. In case of a Ni interlayer, Ni is in contact with the substrate and NiSi is the first phase to form at low heating temperature. Once NiSi is formed completely, CoSi starts to form. Then the disilicide nucleates at the interface of NiSi and CoSi. In case of a Ni cap layer, NiSi is also formed. However, in this case Ni has to diffuse through the Co layer in order to reach the Si, thus first allowing CoSi formation. In the case of Ni addition, no preferential orientation is expected since the CoSi₂ nucleates at the NiSi/CoSi interface. Where a NiSi layer is formed, a separate first heating step may not be required as the disilicide phase already forms at 400° C. Depositing the Ni/Co alloy or stacks at an elevated temperature would alleviate the need for a separate first heating step as at this temperature already the first transformation to silicidecobalt can take place, the exact temperature depending on the nickel content.

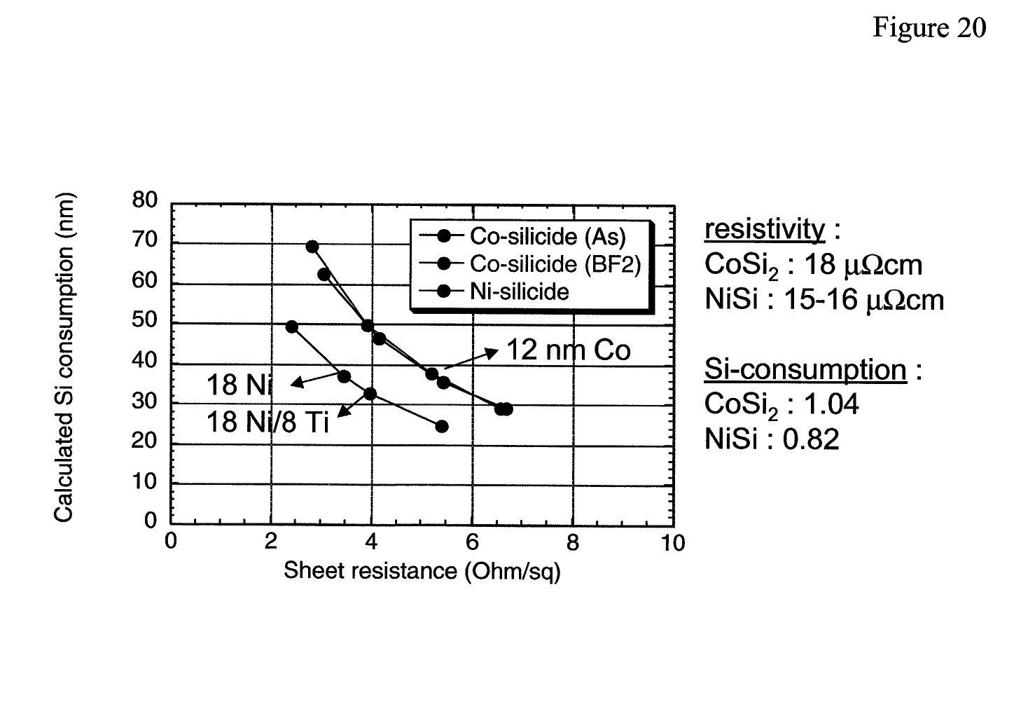

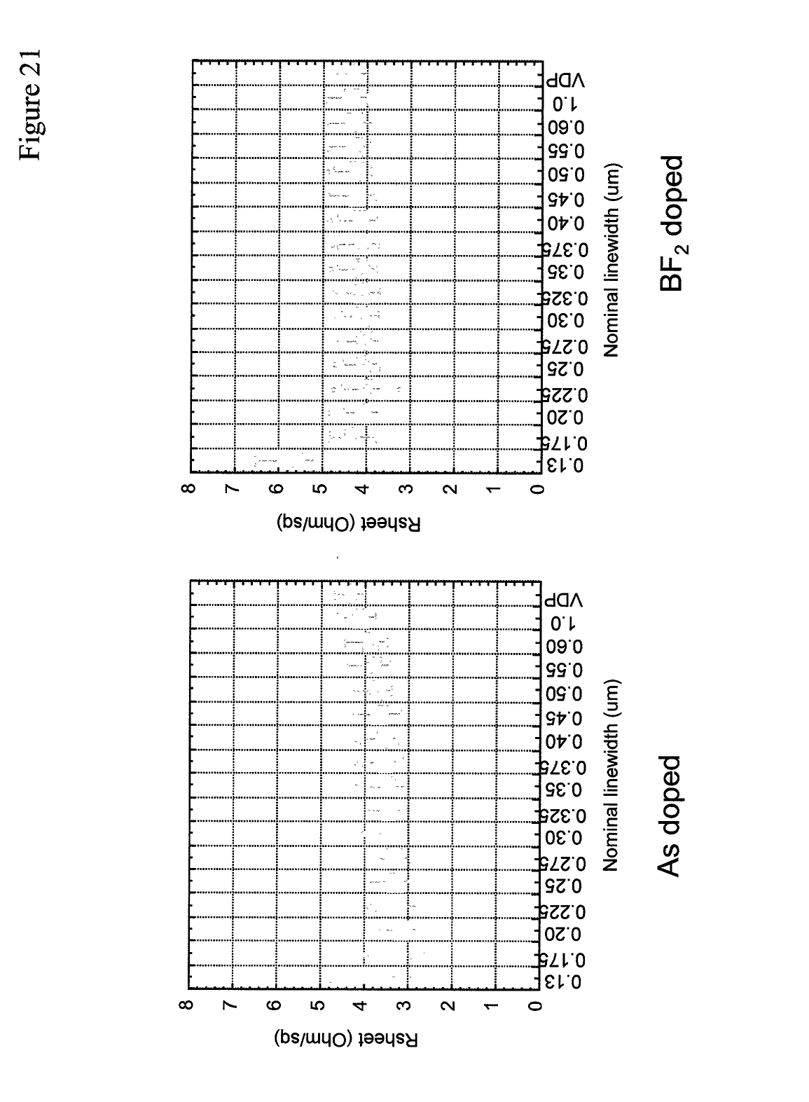

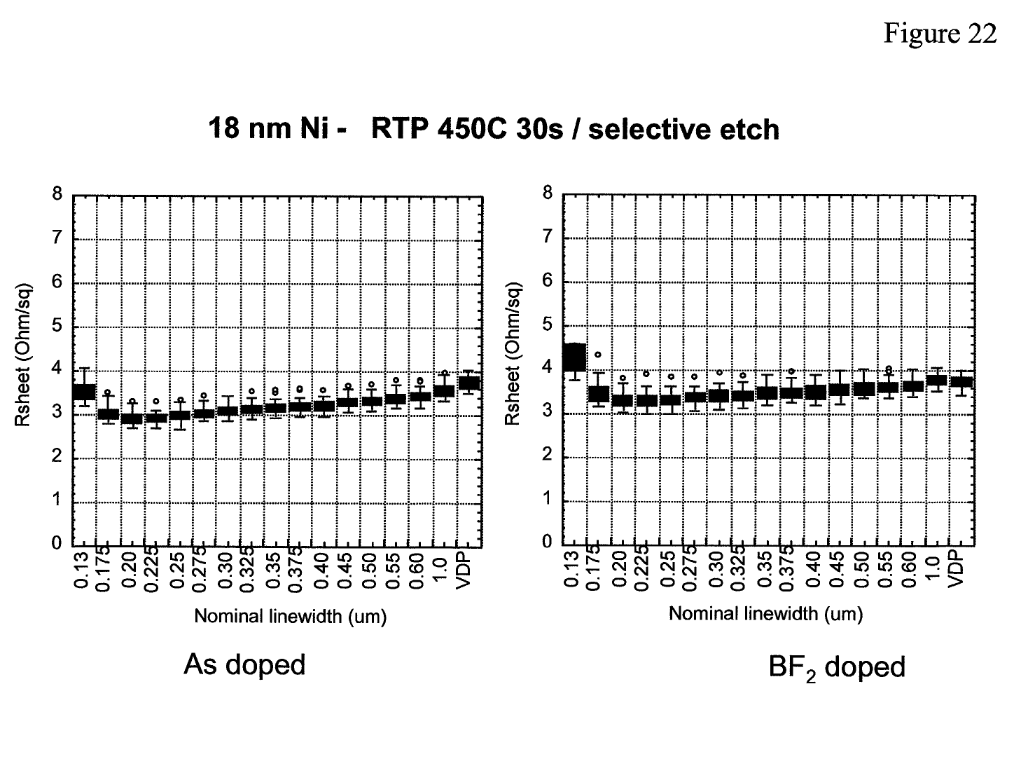

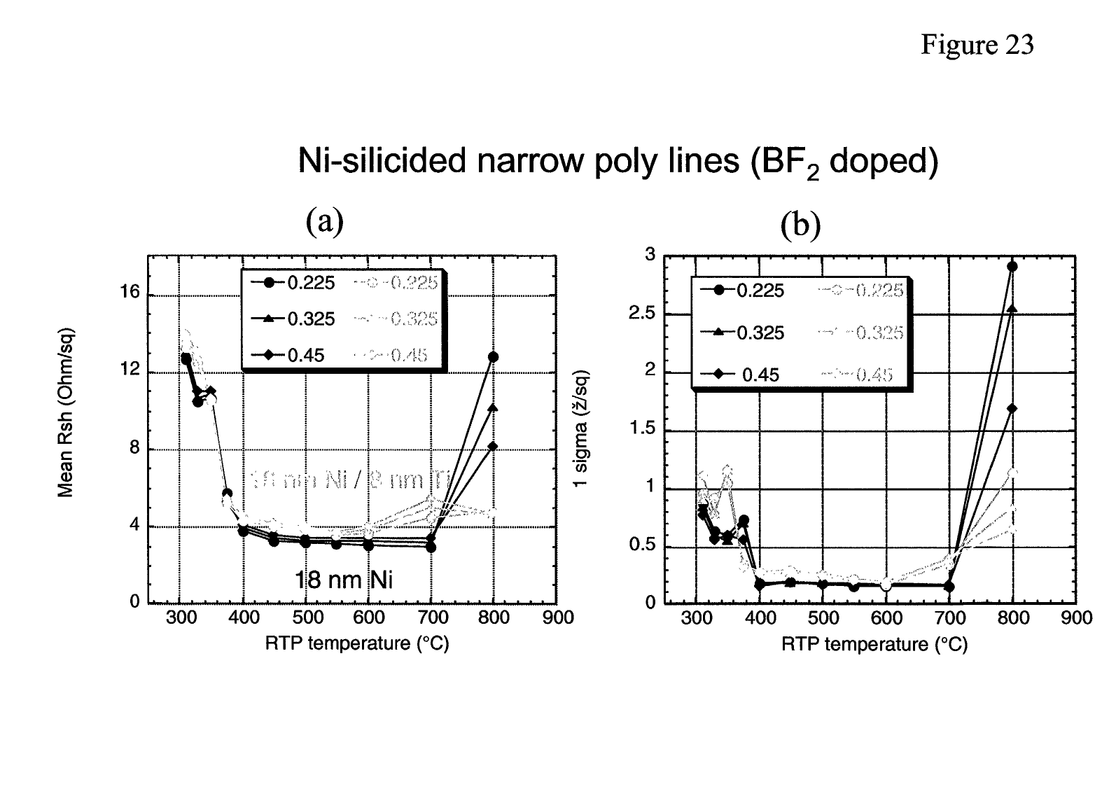

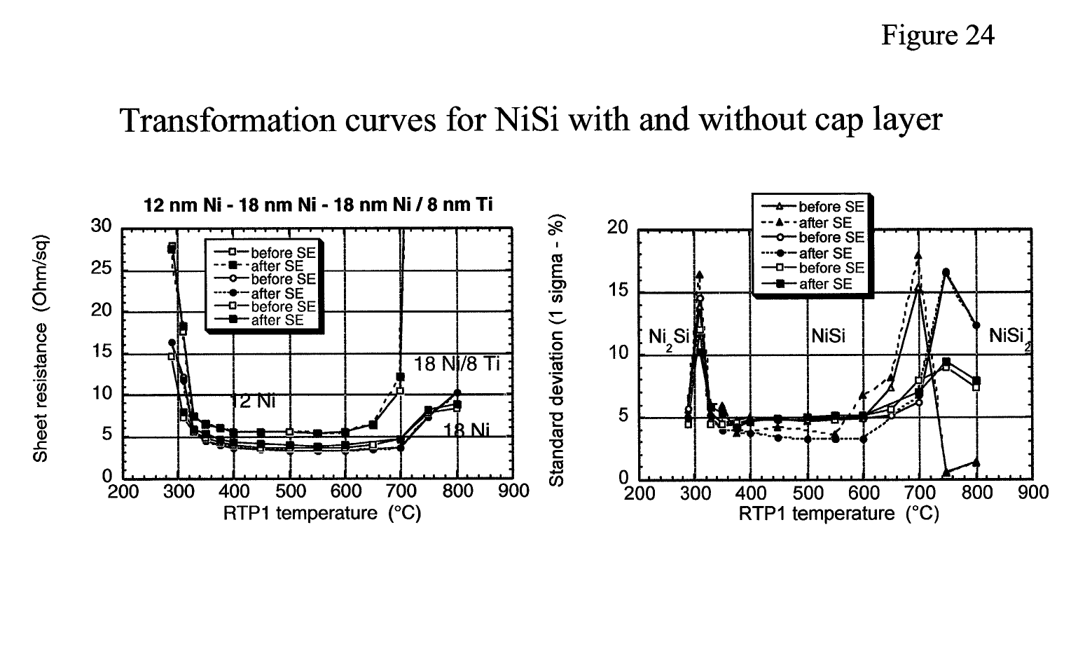

In another embodiment of the invention a polycrystalline nickelsilicide (NiSi) on silicon is formed. An advantage of nickelsilicide is lower consumption of the silicon at the first interface compared to silicidecobalt, as shown in FIG. 20. FIG. 21 and 22 represent the sheet resistance on polysilicon lines of nickelsilicide with or without a Ti capping layer. The use of the Ti capping layer is not needed to ensure proper silicide formation on the narrow lines. From the comparison (FIG. 24) of Ni-silicide formation with and without a Ti cap, it follows that the Ti cap plays a less important role than it does in case of Co-silicidation. It is shown above that the Ti cap lowers the activation energy for CoSi formation by eliminating the formation of SiO₂ between the growing CoSi and the Co. For Ni-silicidation, the formation temperature for NiSi formation was found to be almost the same with and without the Ti cap. This indicates that Ni can diffuse more easily through a thin SiO₂ layer than Co. FIG. 23 illustrates the sheet resistance distribution measured on narrow Ni-silicided BF₂-implanted poly lines as function of silicidation temperature. Low sheet resistance and narrow sheet resistance distributions are obtained for temperatures ranging from 400° C. up to 600° C.

In a preferred embodiment, first a layer comprising a nickel alloy is deposited on at least a part of said substrate, said part comprising at least a first and a second part. A capping or getter layer can also be deposited after depositing the nickel layer. Thereafter the silicon substrate is heated at a first temperature being such that a silicidenickel is formed on said first part. After the heating step the silicon substrate is treated with at least one chemical solution, selectively removing the remaining non-silicidenickel and/or said getter metal and/or nickel and/or nickel-getter-metal alloys from said silicon substrate. Next a second heating step is performed to form the desired polycrystalline nickelsilicide layer on said first part of said substrate.

Instead of having a separate depositing of the capping or getter layer, the getter material can already be included in the nickel alloy.

Instead of having a separate first heating step this heating step can be executed while depositing said first layer or without breaking the vacuum.

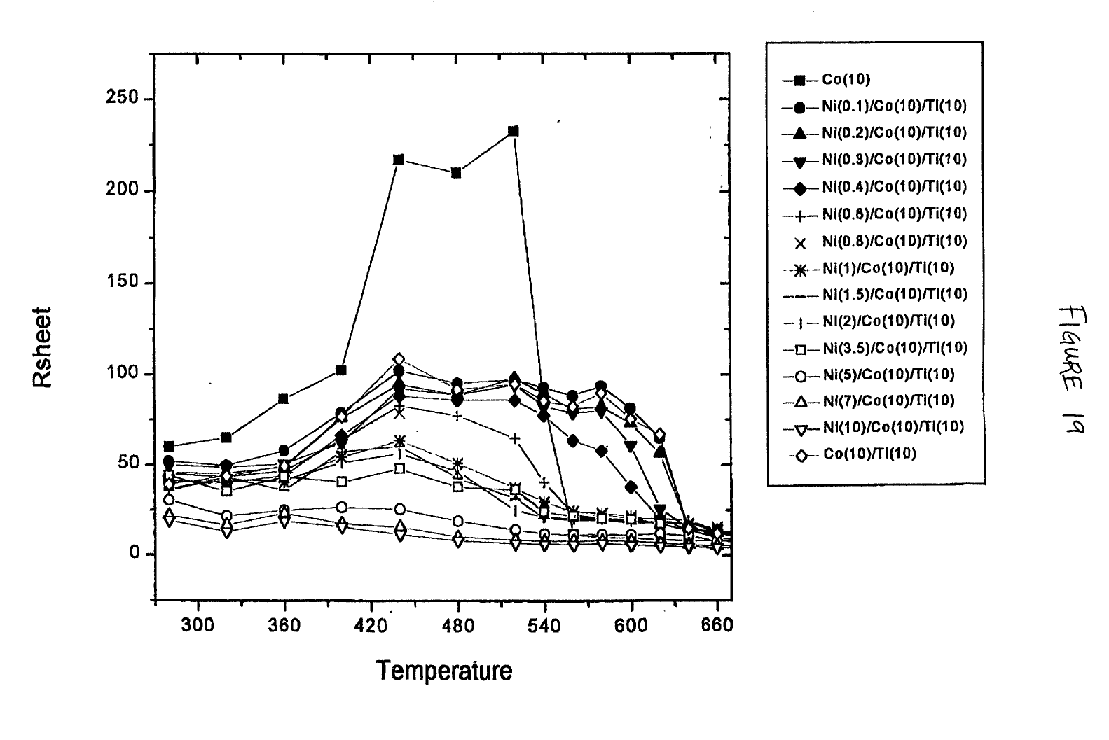

From measurements on transistors made according to the best mode embodiment, it is clear that the specific resistivity of the CoₓNi₍ₗ₋ₓ₎Si₂ layer is similar to that of the CoSi₂ layer with the same Si consumption (see, e.g., FIG. 19).

What is claimed is:

1. A method of forming a silicidecobalt on a silicon substrate, said substrate having a part, said part having a first region capable of undergoing a silicide reaction and a second region incapable of undergoing a silicide reaction, said method comprising:
depositing a first layer structure comprising cobalt and nickel on said part of said substrate; and
heating said silicon substrate at a first temperature for a first time period whereby a silicidecobalt is formed on said first region.

2. The method of claim 1, further comprising the step of depositing a metal getter layer on said first layer structure.

3. The method of claim 1, further comprising:
treating said silicon substrate with at least one chemical solution capable of removing an unwanted material from said substrate, wherein said treating step is conducted after said step of heating said silicon substrate at a first temperature; and thereafter
heating said silicon substrate at a second temperature for a second time period whereby cobalt disilicide is formed on said first region.

4. The method of claim 3, wherein said chemical solution comprises NH₄OH.

5. The method of claim 3, wherein said chemical solution comprises H₂SO₄.

6. The method of claim 3, further comprising the step of growing a passivation layer on top of said silicidecobalt layer, wherein said growing step occurs during said treating step.

7. The method of claim 6, wherein said passivation layer is a thin layer.

8. The method of claim 7, wherein said passivation layer has a thickness of about 5 nm.

9. The method of claim 2, wherein said getter layer consists essentially of a refractory metal.

10. The method of claim 9, wherein said refractory metal comprises titanium.

11. The method of claim 1, wherein said first layer structure comprises an alloy of nickel and cobalt.

12. The method of claim 11, wherein said alloy of nickel and cobalt comprises less than about 25% nickel.

13. The method of claim 12, wherein said alloy of Ni and Co comprises less than about 15% nickel.

14. The method of claim 1, wherein said first layer structure comprises at least one nickel layer and at least one cobalt layer.

15. The method of claim 14, wherein said nickel layer has a thickness from about 0.5 nm to about 50 nm, and wherein said cobalt layer has a thickness from about 1 nm to about 40 nm.

16. The method of claim 14, wherein said nickel layer is deposited on said substrate and has a thickness of about 3 nm and wherein said cobalt layer is deposited on said nickel layer and has a thickness of about 9 nm.

17. The method of claim 2, wherein said first layer structure comprises a nickel layer and a cobalt layer, and wherein said getter layer comprises a titanium layer.

18. The method of claim 17, wherein said nickel layer has a thickness of from about 0.5 nm to about 50 nm, wherein said cobalt layer has a thickness of from about 1 nm to about 40 nm, and wherein said titanium layer has a thickness of less than about 20 nm.

19. The method of claim 17, wherein said nickel layer is deposited on said substrate and has a thickness of about 3 nm, wherein said cobalt layer is deposited on said nickel layer and has a thickness of about 9 nm, and wherein said titanium layer has a thickness of about 8 nm.

20. The method of claim 1, wherein said heating step is performed during said depositing step.

21. The method of claim 3, wherein said second temperature is higher than said first temperature.

22. The method of claim 3, wherein said first temperature is from about 300° C. to about 700° C., wherein said first time period is from about 10 seconds to about 100 seconds, wherein said second temperature is from about 400° C. to about 1000° C., and wherein said second time period is from about 10 seconds to about 100 seconds.

23. The method of claim 3, wherein said first temperature is about 550° C., wherein said first time period is about 30 seconds, wherein said second temperature is about 700° C., and wherein said second time period is about 30 seconds.

24. The method of either claim 1 or 2, wherein said depositing comprises sputter deposition.

25. The method of either claim 1 or 2, wherein said depositing steps comprise sputter deposition under a vacuum in a vacuum system, and wherein the vacuum is not broken in-between said depositing steps.

26. The method of claim 3, wherein said cobalt disilicide comprises a polycrystalline self-aligned cobalt disilicide, and wherein said substrate further comprises a metal oxide semiconductor transistor, said transistor having an actual gate length of about 0.25 μm or smaller and having a source region, a drain region, and a gate region.

27. The method of claim 26, wherein said actual gate length is about 0.18 μm or smaller.

28. The method of claim 1, further comprising:
defining an active area within said silicon substrate;
growing an oxide on at least a portion of said active area of said substrate;
depositing a polysilicon layer on said oxide; and
defining a gate region, a source region, and a drain region within said active area thereby forming a transistor, said gate region, source region and drain region forming said first region of said part of said substrate.

29. A method of forming a polycrystalline cobalt disilicide on a silicon substrate, said substrate having a part, said part having a first region capable of undergoing a silicide reaction and a second region incapable of undergoing a silicide reaction, said method comprising:
depositing a layer structure comprising cobalt, nickel and a refractory metal on said part of said substrate; thereafter
heating said silicon substrate at a silicidecobalt-forming temperature whereby a silicidecobalt is formed on said first region;
treating said substrate with at least one chemical solution, said chemical solution being capable of selectively removing from said substrate cobalt in a form other than silicidecobalt, a refractory metal, and a cobalt refractory metal alloy; and thereafter
heating said substrate at a cobalt disilicide-forming temperature whereby a polycrystalline cobalt disilicide layer is formed on said first region of said part of said substrate.

30. The method of claim 29 wherein said depositing step comprises sputter deposition in a vacuum system using a sputter target comprising a mixture of cobalt, nickel, and said refractory metal.

31. The method of claim 29, wherein said cobalt disilicide-forming temperature is higher than said silicidecobalt-forming temperature.

32. A method of forming a silicidenickel on a silicon substrate, said substrate having a part, said part having a first region capable of undergoing a silicide reaction and a second region incapable of undergoing a silicide reaction, the method comprising:
depositing a first layer comprising nickel on said part of said substrate; and thereafter
heating said silicon substrate at a first temperature whereby silicidenickel is formed on said first region.

33. The method of claim 32, further comprising the step of depositing a metal getter layer on said first layer.

34. The method of claim 32, wherein said first layer further comprises a refractory metal.

35. The method of claim 32, further comprising:
treating said substrate with at least one chemical solution, said chemical solution being capable of selectively removing from said substrate a substance selected from the group consisting of a non-silicidenickel form of nickel, a getter metal, and a nickel-getter metal alloy, wherein said treating step is conducted after said step of heating said silicon substrate at a first temperature; and thereafter
heating said substrate at a second temperature whereby polycrystalline nickelsilicide is formed on said first region of said part of said substrate.

36. The method of claim 32, wherein said step of heating said substrate at a first temperature is executed while depositing said first layer.

37. A method of forming a polycrystalline nickelsilicide on a silicon substrate, said substrate having a part, said part having a first region capable of undergoing a silicide reaction and a second region incapable of undergoing a silicide reaction, the method comprising:
depositing a first layer comprising nickel on said part of said substrate;
depositing a metal getter layer on said first layer; thereafter
heating said substrate at a silicidenickel-forming temperature whereby a silicidenickel layer is formed on said first region;
treating said substrate with at least one chemical solution, said chemical solution being capable of selectively removing from said substrate a substance selected from the group consisting of a non-silicidenickel form of nickel, a getter metal, and a nickel-getter metal alloy; and
heating said substrate at a polycrystalline nickelsilicide-forming temperature whereby a polycrystalline nickelsilicide layer is formed on said first region of said part of said substrate.

38. A method of forming a silicidenickel on a silicon substrate, said substrate having a part, said part having a first region capable of undergoing a silicide reaction and a second region incapable of undergoing a silicide reaction, the method comprising:
depositing a first layer comprising nickel on said part of said substrate;
depositing a metal getter layer on said first layer; thereafter
heating said substrate at a silicidenickel-forming temperature whereby a silicidenickel layer is formed on said first region; and thereafter
treating said substrate with at least one chemical solution, said chemical solution being capable of selectively removing from said substrate a substance selected from the group consisting of a non-silicidenickel form of nickel, a getter metal, and a nickel-getter metal alloy.

39. A method of forming a polycrystalline palladiumsilicide on a silicon substrate, said substrate having a part, said part having a first region capable of undergoing a silicide reaction and a second region incapable of undergoing a silicide reaction, the method comprising:
depositing a first layer comprising palladium on said part of said substrate;
depositing a metal getter layer on said first layer; thereafter
heating said silicon substrate at a silicidepalladium-forming temperature whereby a silicidepalladium is formed on said first region;
treating said substrate with at least one chemical solution, said chemical solution being capable of selectively removing from said substrate a substance selected from the group consisting of a non-silicidepalladium form of palladium, a getter metal, and a palladium-getter metal alloy; and thereafter
heating said substrate at a polycrystalline palladiumsilicide-forming temperature whereby a polycrystalline palladiumsilicide layer is formed on said first region of said part of said substrate.

40. A method of forming a polycrystalline platinumsilicide on a silicon substrate, said substrate having a part, said part having a first region capable of undergoing a silicide reaction and a second region incapable of undergoing a silicide reaction, said method comprising:
depositing a first layer comprising platinum on said part of said substrate;
depositing a metal getter layer on said first layer; thereafter
heating said silicon substrate at a silicideplatinum-forming temperature whereby a silicideplatinum is formed on said first region;
treating said substrate with at least one chemical solution, said chemical solution being capable of selectively removing from said substrate a substance selected from the group consisting of a non-silicideplatinum form of platinum, a getter metal, and a platinum-getter metal alloy; and thereafter
heating said substrate at a polycrystalline platinumsilicide-forming temperature whereby a polycrystalline platinumsilicide layer is formed on said first region of said part of said substrate.

41. The method of claim 3, wherein said chemical solution is capable of selectively removing from said substrate a substance selected from the group consisting of a non-silicidecobalt form of cobalt, a getter metal, nickel, a nickel-getter metal alloy, a nickel-cobalt alloy, and a cobalt-getter metal alloy.

42. The method of claim 3, wherein said cobalt disilicide comprises polycrystalline cobalt disilicide.
